(19) United States
(12) Patent Application Publication
(10) Pub. No.: US 2023/0009665 A1
(43) Pub. Date: Jan. 12, 2023

(54) SIGNAL PROCESSING CIRCUIT

(71) Applicant: FUJITSU LIMITED, Kawasaki-shi (JP)

(72) Inventor: Yoichi Kawano, Setagaya (JP)

(73) Assignee: FUJITSU LIMITED, Kawasaki-shi (JP)

(21) Appl. No.: 17/716,472

(22) Filed: Apr. 8, 2022

(30) Foreign Application Priority Data
Jul. 12, 2021 (JP) 2021-114826

(51) Int. Cl. H03G 3/30; H03K 5/01

(52) U.S. Cl. CPC H03G 3/3036; H03K 5/01; H03K 2005/00078

(57) ABSTRACT

A signal processing circuit includes a signal path for outputting a first signal included in an input signal from a first output terminal to another signal processor; branch paths one of which extends from a top position located at a position on the signal path and the others which extend from associated branch positions that divide the signal path starting from the top position to the first output terminal into segments in each of which a first amount of delay obtained by equally dividing an amount of delay caused by the signal path and that is added to the first signal; a switch connected to each of the branch paths and switches whether to allow a second signal other than the first signal included in the input signal to pass through the connected branch paths; a variable gain amplifier connected to each of the switches and amplifies the second signal.

### CROSS-REFERENCE TO RELATED APPLICATION

This application is based upon and claims the benefit of priority of the prior Japanese Patent Application No. 2021-114826, filed on Jul. 12, 2021, the entire contents of which are incorporated herein by reference.

### FIELD

The embodiments discussed herein are related to a signal processing circuit.

### BACKGROUND

Regarding base station devices in the fifth generation mobile communication (5G), there is a technology called multibeam multiplexing for multiplexing a plurality of different data streams and transmitting the data streams from an antenna array. Here, multibeam multiplexing will be described by using an example of multiplexing four beams.

In a multibeam multiplexing system used in practice, both of a vertical (V) polarized wave and a horizontal (H) polarized wave of antenna is able to be transmitted by using a single patch antenna, so that it is assumed that the four beams are further subjected to VH polarized wave division multiplexing. In other words, eight pieces of different data are supplied to a single piece of antenna. As a result, in a multiplexing system using four beams, wiring of signal lines are complicated. Furthermore, since a data signal needs to have a differential configuration in order to secure propagation quality, there may be a case in which the signal lines sometimes need to be doubled. In this case, in an eight-beam multiplexing configuration under the assumption of VH polarized wave division multiplexing, the number of signal lines is 16, and thus, wiring of the signal lines is more complicated.

In an interior of a semiconductor chip, for example, if a silicon complementary metal oxide semiconductor (Si-CMOS) is used, in general, it is possible to lay out the wiring including 10 or more layers by setting a line width and a gap to about 1 μm. As a result, it is possible to implement the complicated wiring used for multiplexing four beams described above.

In contrast, in a phased array substrate in which chips are disposed in an array manner, the minimum width of the line and a gap about 100 μm, which is large, it is difficult to lay out the wiring of the signals used for multiplexing four beams.

Here, in order to alleviate complication of substrate wiring, a configuration in which each of the data signals passing through a single piece of chip is transmitted to the adjacent chip in a manner of a bucket brigade (daisy chain) is often used. For example, if 16 chips are disposed in a 4×4 array, the 16 differential data signals are input to 16 signal lines that are connected to the chip located at one end portion, and are supplied to the chip at the other end portion by sequentially being delivered to the next chip among three chips using a bucket brigade technique. The configuration using such a daisy chain technique is generally used in a low-speed control signal used for, for example, serial peripheral interface (SPI) control.

Here, a case in which a signal is propagated among four chips C1 C4 that are disposed in series in a daisy chain manner is considered. In this case, for example, four pieces of data with V polarized wave and four pieces of data with H polarized wave are input to the chip C1, and are propagated to the chips C2 to C4 via a substrate. Furthermore, an output signal with V polarized wave and an output signal with H polarized wave are output from each of the chips C1 to C4.

As a technology related to a system in which signals pass through a plurality of signal output devices, there is a technology for compensating, in a base stations that are connected in a cascade connection manner, a delayed signal transmitted through each of the base stations by controlling an amount of delay on the basis of a connection order of the base stations.
Patent Literature 1: International Publication Pamphlet No. WO 2017/130301

However, if a configuration of a daisy chain is used, a delay due to a signal transfer occurs at the timing at which an output signal is output from each of the chips. For example, a delay of a case in which the chips C1 to C4 are linked in a daisy chain manner is considered. When a propagation delay of a signal passing through a single chip is denoted by τ1, and a propagation delay on the substrate is denoted by τ2, a propagation delay between an output signal that is output from the chip C1 and an output signal that is output from the chip C4 is 3(τ1−τ2). If a data bandwidth is a 400 MHz class or an 800 MHz class used in 5G, a delay that is larger than this amount of delay occurs, which is a problem.

For example, as an example of a modulation wave, a description will be given of a simulation result of an amount of delay in the case where two tone signals in which a frequency difference is 400 MHz are input to the four chips C1 to C4 disposed in series. Here, since data uses an intermediate frequency (IF) frequency band, 5 GHz and 5.4 GHz are set. In this case, a beat waveform in which two waves associated with two tones are combined is observed, and a temporal difference of the waveform between the output signal that is output from the chip C1 and the output signal that is output from the chip C4 is about 250 ps. This corresponds to 1/10 of a wavelength with respect to the data bandwidth at 400 MHz, resulting in an adverse effect on signal quality.

Furthermore, in the technology for controlling an amount of delay using a connection order of base stations, a layout of signal lines or the like is not considered, and it is thus difficult to use this technology to compensate a delay caused by signal transmission in the chips that are mounted on a substrate, that are connected in a daisy chain manner, and that performs beam multiplexing.

### SUMMARY

According to an aspect of an embodiment, a signal processing circuit includes a signal path for outputting a first signal included in an input signal from a first output terminal to another signal processor; branch paths one of which extends from a top position located at a position on the signal path and the others of which extend from associated branch positions that divide the signal path starting from the top position to the first output terminal into segments in each of which a first amount of delay that is obtained by equally dividing an amount of delay that is caused by the signal path and that is added to the first signal is added; a switch that is connected to each of the branch paths and that switches whether to allow a second signal other than the first signal included in the input signal to pass through the connected branch paths; a variable gain amplifier that is connected to each of the switches and that amplifies the second signal; and a delay adding unit that adds a predetermined amount of delay to the second signals that are output from the respective variable gain amplifiers in accordance with the branch positions to which the respective branch paths through which the respective second signals pass are connected, and outputs the second signals from a second output terminal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating, in outline, a wireless communication apparatus;

FIG. 2 is a diagram illustrating an example of wiring of a chip mounting substrate and an array antenna;

FIG. 3 is an image diagram illustrating multiplexing beams that are output from a phased array antenna;

FIG. 4 is a diagram illustrating a chip mounting substrate in detail;

FIG. 5 is a diagram illustrating a signal processing unit in detail;

FIG. 6 is a diagram illustrating, in outline, a distribution unit;

FIG. 7 is a diagram illustrating a delay caused by a transfer of transmission signals between distribution delay circuits that are connected in a daisy chain manner;

FIG. 8 is a circuit configuration diagram of a distribution delay circuit according to a first embodiment;

FIG. 9 is a diagram illustrating distribution delay circuits that are connected in a daisy chain manner;

FIG. 10 is a diagram illustrating the flow of a signal in a top distribution delay circuit;

FIG. 11 is a flowchart illustrating a signal output process performed in the distribution delay circuit;

FIG. 12 is a circuit configuration diagram of a distribution delay circuit according to a second embodiment;

FIG. 13 is a diagram illustrating a waveform output obtained when the distribution delay circuit according to the second embodiment is used; and

FIG. 14 is a diagram illustrating gain characteristics of an output from each of the chips in the case where the distribution delay circuit according to the second embodiment is used.

### DESCRIPTION OF EMBODIMENTS

Preferred embodiments of the present invention will be explained with reference to accompanying drawings. Furthermore, the signal processing circuit disclosed in the present invention is not limited by the embodiments described below.

### [a] First Embodiment

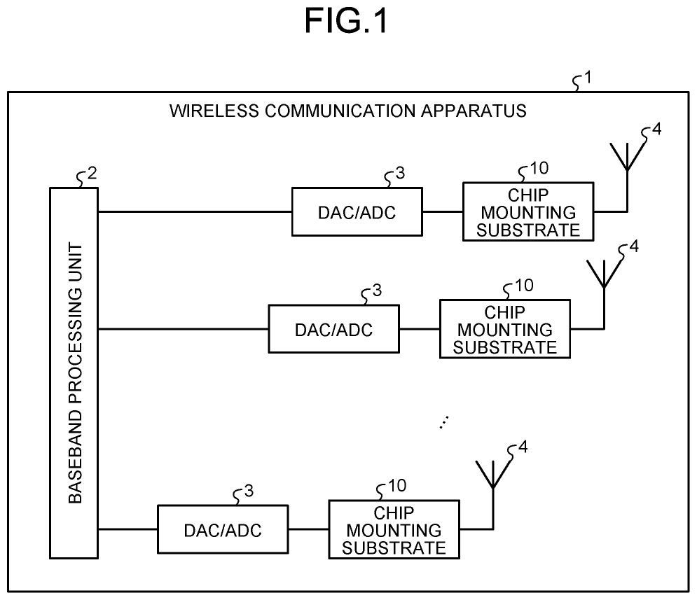

FIG. 1 is a diagram illustrating, in outline, a wireless communication apparatus. A wireless communication apparatus 1 according to an embodiment includes, as illustrated in FIG. 1, a baseband processing unit 2, digital-to-analog converters (DACs)/analog-to-digital converters (ADCs) 3, antennas 4, and chip mounting substrates 10.

The baseband processing unit 2 performs a baseband process for performing a process of encoding and modulating on data to be transmitted. Then, the baseband processing unit 2 outputs, to the DACs/ADCs 3, a baseband signal that has been subjected to encoding and modulation process.

Furthermore, the baseband processing unit 2 receives an input of a reception signal from each of the DACs/ADCs 3. Then, the baseband processing unit 2 generates reception data by performing a process of demodulating and decoding a reception signal that is the baseband signal. After that, the baseband processing unit 2 outputs the generated reception data to a network (not illustrated) located in an upper level.

Each of the DACs/ADCs 3 receives an input of the baseband signal corresponding to transmission data from the baseband processing unit 2. Then, each of the DACs/ADCs 3 converts the baseband signal that is the acquired digital signal to an analog signal. After that, each of the DACs/ADCs 3 outputs the baseband signal that has been converted to the analog signal to the chip mounting substrate 10.

Furthermore, each of the DACs/ADCs 3 receives an input of the reception signal that corresponds to an analog signal from the chip mounting substrate 10. Then, each of the DACs/ADCs 3 converts the reception signal from the analog signal to a digital signal. After that, each of the DACs/ADCs 3 outputs the reception signal that has been converted to the digital signal to the baseband processing unit 2.

The chip mounting substrates 10 are radio frequency (RF) units. Each of the chip mounting substrates 10 receives an input of a baseband signal including the transmission data converted to the digital signal from the respective DACs/ADCs 3. Then, each of the chip mounting substrates 10 performs quadrature modulation on the baseband signal to convert the baseband signal to the radio frequency and places the signal on a carrier wave. Each of the chip mounting substrates 10 performs a process of quadrature modulation on the signal at an intermediate frequency (IF) bandwidth corresponding to an intermediate frequency. After that, each of the chip mounting substrates 10 amplifies the transmission signal after having converted the transmission signal to a millimeter waveband, and then, outputs the signal from the antenna 4.

Furthermore, each of the chip mounting substrates 10 receives an input of a reception signal from the respective antennas 4. Then, each of the chip mounting substrates 10 performs quadrature demodulation on the reception signal to convert the signal to a baseband signal. After that, each of the chip mounting substrates 10 outputs the reception signal converted to the baseband signal to the respective DACs/ADCs 3.

The antennas 4 are phased array antennas each having a plurality of patch antennas. In other words, each of the antennas 4 transmits a signal by using a plurality of patch antennas. Furthermore, it is possible to transmit a signal by multiplexing a plurality of signals from a single patch antenna. For example, in a case of multiplexing four beams, four types of signals are output from a single patch antenna. Furthermore, each of the patch antennas in the associated antennas 4 sends both of the V polarized wave and the H polarized wave. In other words, in a case of multiplexing four beams, each of the patch antennas simultaneously sends eight signals.

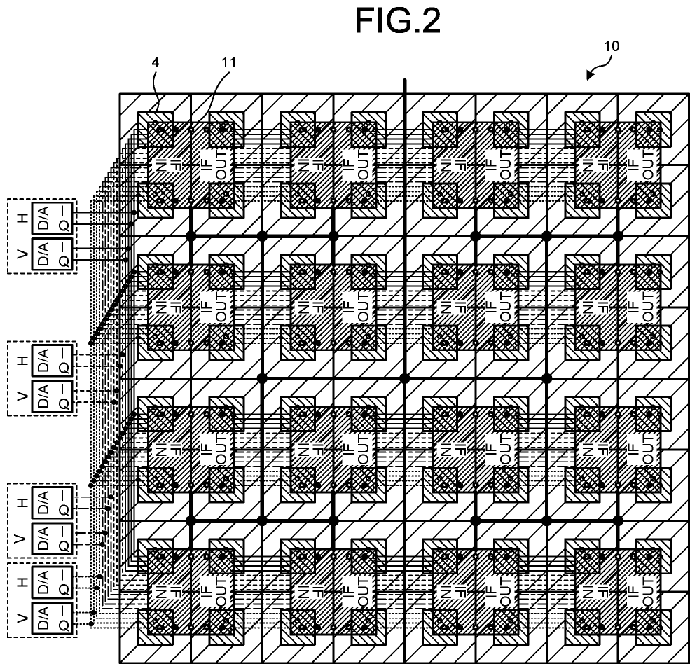

FIG. 2 is a diagram illustrating an example of wiring of a chip mounting substrate and array antennas. Each of the antennas 4 illustrated in FIG. 2 indicates a single piece of patch antenna. The antennas 4 illustrated in FIG. 2 are 8×8 phased array antenna. In other words, in the antennas 4 illustrated in FIG. 2, a piece of signal is generated from each of 64 signals that are output from the respective 64 patch antennas. In FIG. 2, the antennas 4 output the V polarized wave and the H polarized wave of four different transmission signals at a time.

On the chip mounting substrate 10, in FIG. 2, 16 chips 11 are mounted. Each of the chips 11 causes a signal to be output from each of the four patch antennas. In other words, each of the chips 11 performs a process on the signal that is output from the four patch antennas and a process on the signal that is received by the four patch antenna. In order to simplify a substrate layout, the chips 11 illustrated in FIG. 2 are connected such that the chips 11 arranged in a row in a lateral direction on the plane of the drawing are connected in a daisy chain manner. A signal of the other chips 11 connected in a daisy chain manner is input to the associated chips 11 located on the left end on the plane of the drawing. Then, the signal is delivered, by way of the other chips 11, to the chip 11 that actually performs a process on the subject signal.

In FIG. 2, a differential configuration is used to secure propagation quality in a case of multiplexing four beams. In other words, among the chips 11 connected in a daisy chain manner illustrated in FIG. 2, the number of paths of the V polarized wave and the H polarized wave disposed to each of the four beams is doubled in a differential configuration, so that a total of 16 signal lines are used for the connection. Furthermore, a signal line for inputting a local signal that drives a mixer is connected to each of the chips 11.

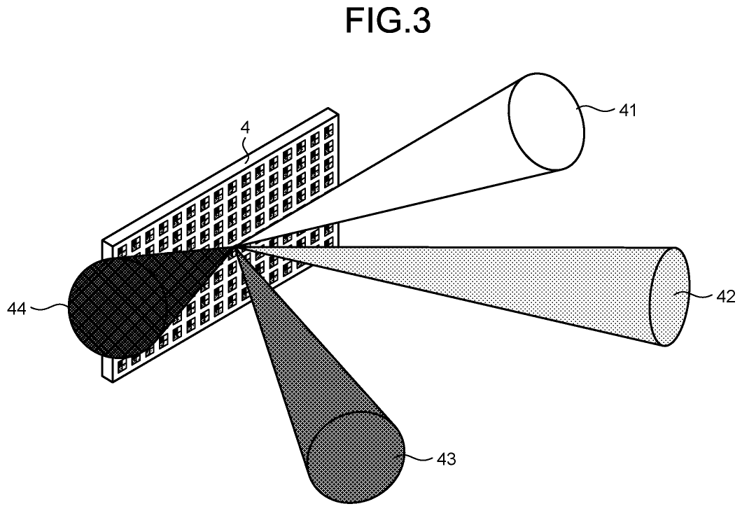

FIG. 3 is an image diagram illustrating multiple beams that are output from a phased array antenna. For example, in a case of multiplexing four beams, signals 41 to 44 are sent from the antenna 4. The signals 41 to 44 are different signals and are signals addressed to, for example, different users. Each of the signals 41 to 44 includes a V polarized wave and an H polarized wave.

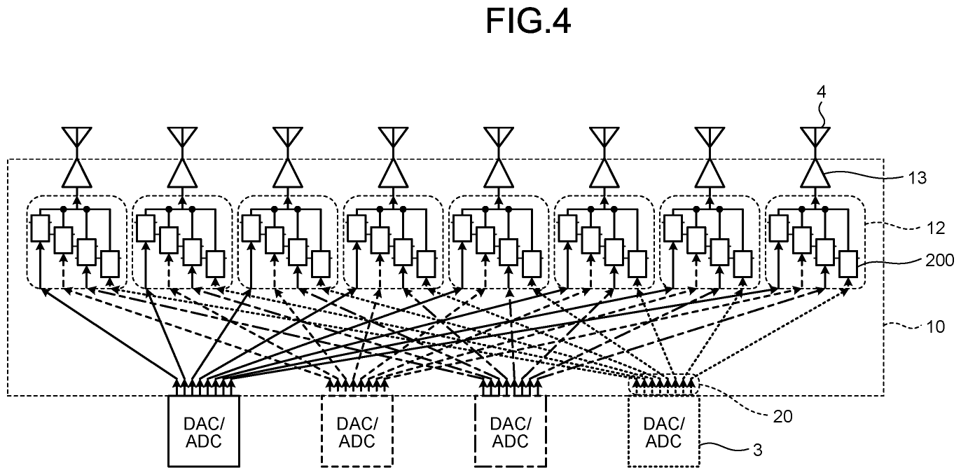

FIG. 4 is a diagram illustrating a chip mounting substrate in detail. The chip mounting substrate 10 includes amplifiers 13, distribution units 20 and signal processing units 12. This is an example of a case of multiplexing four beams, in the chip mounting substrate 10, a total of eight transmission signals each of which includes the V polarized wave and the H polarized wave that are input from each of the associated DACs/ADCs 3 and has a differential configuration are input to the respective chips 11. However, FIG. 4 collectively illustrates the V polarized wave and the H polarized wave as a single signal. For example, the signal 41 illustrated in FIG. 3 is generated from the eight transmission signals that are output from the single piece of the DAC/ADC 3 illustrated in FIG. 4.

As a specific connection state of the signal line, the signals are collectively input to the chip 11 located at an input end out of the four chips 11 that are connected in a daisy chain manner, and are delivered to each of the chips 11 in a daisy chain manner. In other words, in FIG. 4, the eight transmission signals that are input from the respective DACs/ADCs 3 are delivered to each of the respective antennas 4 by using different paths; however, in practice, in the distribution unit 20, the signals are distributed to a transmission signal addressed to each of the antennas 4 in a daisy chain manner. A mechanism for distributing the transmission signals addressed to each of the antennas 4 in the daisy chain manner will be described in detail later.

Then, each of the transmission signals is transmitted to different signal paths included in the signal processing unit 12. In each of the signal paths included in the signal processing unit 12, an output processing circuit 200 is disposed. A combination of one of the signal paths each of which outputs the transmission signal that is connected in the distribution unit 20 in a daisy chain manner and that is distributed and one of the output processing circuits 200 associated with the subject signal path is included in a single piece of the chip 11.

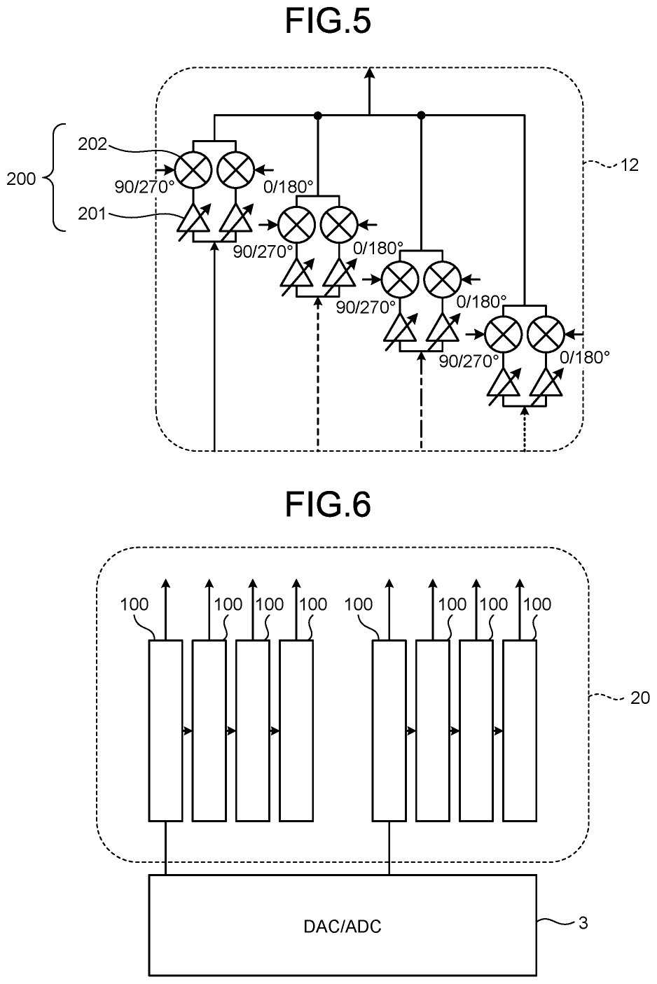

FIG. 5 is a configuration diagram illustrating the signal processing unit in detail. In the signal processing unit 12, the output processing circuits 200 are disposed to each of the signal paths. Each of the output processing circuit 200 includes two variable gain amplifiers 201 and two mixers 202.

The transmission signal that is input from the distribution unit 20 is distributed into two, and is input to each of the two variable gain amplifiers 201. Each of the variable gain amplifiers 201 performs quadrature modulation on the associated transmission signals by rotating the phase of the transmission signal that is input on the basis of the associated gain. Then, each of the variable gain amplifiers 201 outputs the transmission signal that has been subjected to quadrature modulation to the associated mixers 202.

The mixers 202 are double balanced mixers functioning as a pair. Each of the mixers 202 performs up-conversion on the input transmission signal and converts the signal from an IF signal to a millimeter wave signal. For example, each of the mixers 202 performs up-conversion on the IF signal and converts the signal to a millimeter wave signal at the band of 28 GHz. The signals that have been output from the respective mixers 202 included in the respective output processing circuits 200 associated with the respective four paths are simultaneously sent from one of the patch antennas in the associated antennas 4. The process of quadrature modulation performed by the variable gain amplifiers 201 and up-conversion performed by the mixers 202 is an example of a “predetermined signal process”.

Here, routing of a signal on the chip mounting substrate 10 may be structured in a different substrate configuration by setting, for example, an IF band antenna unit corresponding a portion from the DAC/ADC 3 to the output processing circuit 200 to be MEGTRON (registered trademark) (Meg) 6 and an IF unit corresponding to the signal processing unit 12 to be a substrate formed of Flame Retardant Type (Fr) of 4.

FIG. 6 is a diagram illustrating, in outline, of the distribution unit. The distribution unit 20 includes a plurality of distribution delay circuits 100. The distribution delay circuits 100 mentioned here correspond to an example of “signal processing circuits”. For example, in a case of multiplexing four beams, the four distribution delay circuits 100 are connected in series in a daisy chain manner. In other words, a signal is input to the distribution delay circuit 100 located on one end side of the four distribution delay circuits 100 that are linked in series and a process of sequentially transferring the signal to the adjacent distribution delay circuit 100 is repeated, so that the transmission signal is sent to the distribution delay circuit 100 located in the last stage on the other end. At this time, the distribution delay circuit 100 outputs the transmission signal, out of the received transmission signals, processed by the chip 11 included in the own distribution delay circuit 100 to the output processing circuit 200, and outputs the transmission signal processed by the other chip 11 to the adjacent distribution delay circuit 100.

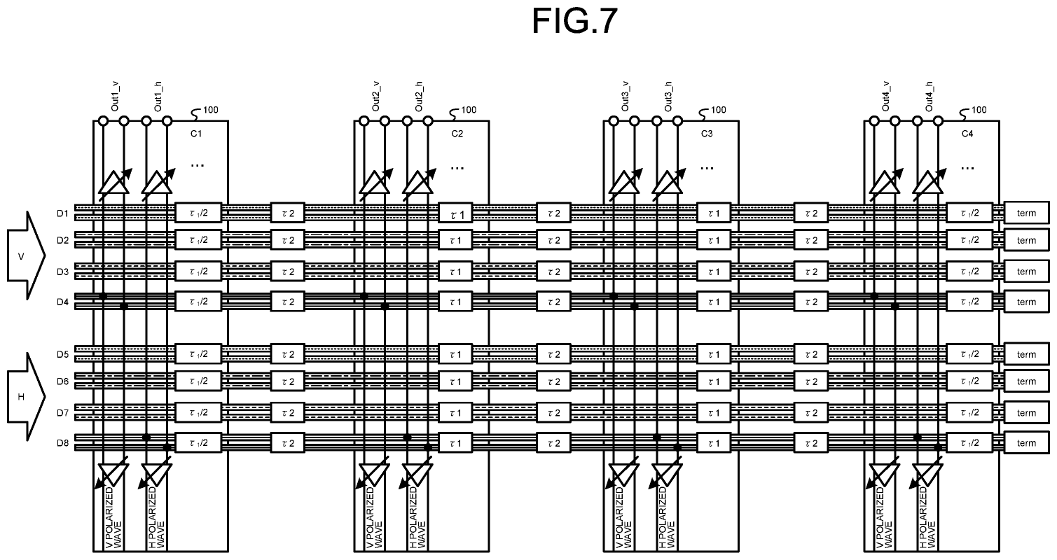

A delay occurs at the time of transferring the transmission signal among the distribution delay circuits 100. As a result, the timing at which a transmission signal is output from each of the distribution delay circuits 100 to the output processing circuits 200 is shifted, and, as a result, the transmission timing of the transmission signal from each of the patch antennas included in the antennas 4 may possibly be shifted. FIG. 7 is a diagram illustrating a delay caused by a transfer of a transmission signal among the distribution delay circuits 100 connected in a daisy chain manner. Here, a delay caused by a transfer of the transmission signal among the chips 11 will be described with reference to FIG. 7. Here, a description will be given in the case where the chips C1 to C4, as the chips 11, are connected in this order in a daisy chain manner. In FIG. 7, signals D1 to D4 denote signals having the V polarized wave processed by each of the chips C4 to C1, whereas signals D5 to D8 denote signals having the H polarized wave processed by each of the chips C4 to C1. Furthermore, Out1_v to Out4_v denote the V polarized waves that are output from the respective chips C1 to C4, whereas Out1_h to Out4_h denote the H polarized waves that are output from the respective chips C1 to C4.

Here, a description will be given by using the signals D1 to D4 as an example. The signal D4 that is input to the chip C1 is output to the antenna 4 as Out1_v. A delay τ₁/2 is added to each of the signals D1 to D3 as a result of passing through the chip C1. Furthermore, a delay of T₂ is added to the signals D1 to D3 on the signal line located between the chip C1 and the chip C2. The signal D3 that is input to the chip C2 is output to the antenna 4 as Out2_v. A delay τ₁ is added to each of the signals D1 and D2 as a result of passing through the chip C2. Furthermore, a delay of τ₂ is added to each of the signals D1 and D2 on the signal line located between the chip C2 and the chip C3. The signal D2 that is input to the chip C3 is output to the antenna 4 as Out3_v. A delay τ₁ is added to the signal D1 as a result of passing through the chip C3. Furthermore, a delay of τ2 is added to the signal D1 on the signal line located between the chip C3 and the chip C4. After that, although a signal is not present, a signal line for adding a delay τ₁/2 is present in the route to the terminator 141. In other words, an amount of delay of 3τ₁+3τ₂ occurs between the transmission timing of the transmission signal that has been output from the chip C1 and the transmission timing of the transmission signal that has been output from the chip C4. The amount of delay of 3τ₁+3τ₂ corresponds to about 250 ps in a case in which the data bandwidth is 400 MHz. This corresponds to 1/10 of the wavelength with respect to the data bandwidth, and thus affects the signal quality. Therefore, it is preferable to adjust an output timing of the transmission signal by using the distribution delay circuit 100 mounted on each of the chips 11 and decrease the amount of delay to a value smaller than or equal to 1/10 of the data bandwidth at a maximum.

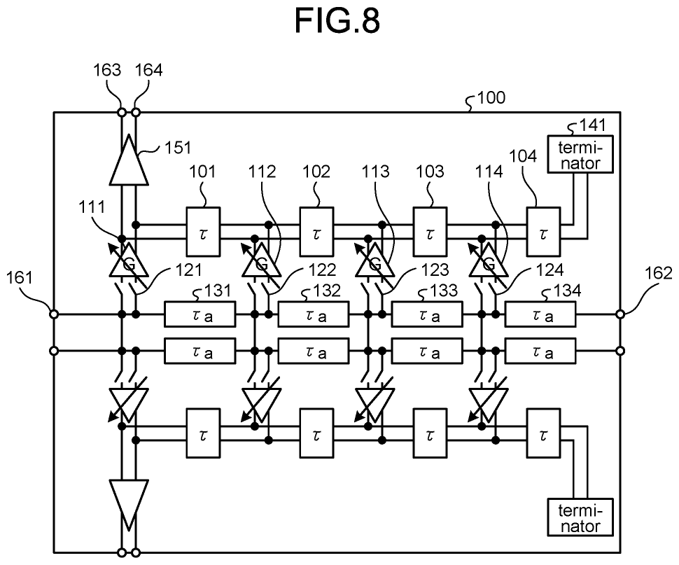

FIG. 8 is a circuit configuration diagram of the distribution delay circuit according to the first embodiment. Here, a circuit configuration of the distribution delay circuit 100 according to the present embodiment will be described with reference to FIG. 8. Here, a configuration in which the V polarized wave is transferred will be described as an example.

The distribution delay circuit 100 includes an input terminal 161 and output terminals 162 to 164. The input terminal 161 is an input terminal for the transmission signal. The output terminal 162 is the output terminal to the subsequent chip 11 connected in a daisy chain manner. In other words, a path from the input terminal 161 to the output terminal 162 is the signal path that is called a Daisy line for transmitting a signal to the subsequent chip 11 connected in a daisy chain manner and is a path through which a first signal transmitted to the subsequent chip 11 passes. Furthermore, the output terminals 163 and 164 are the output terminals for the transmission signal to be output to the output processing circuit 200, and in which two signal paths are provided for a differential configuration.

Furthermore, in the distribution delay circuit 100, four branch paths are provided between the input terminal 161 and the output terminal 162 such that an amount of delay is equally divided. These branch paths are paths through which a second signal corresponding to a signal that is output from the output terminals 163 and 164 corresponding to the second output terminals and that is transmitted to the output processing circuit 200. Here, a value obtained by equally dividing an amount of delay that is added to the signal and that is caused by the signal path between the input terminal 161 and the output terminal 162 into four is denoted by τa. The value denoted by τa corresponds to an example of a “first amount of delay”.

Here, four branch paths are provided because the present embodiment is a case of multiplexing four beams and is a case in which the four chips 11 are connected in a daisy chain manner; however, the number of branch paths depends on the number of chips 11 that are connected in a daisy chain manner. In other words, the same number of branch paths as the number of the chips 11 connected in a daisy chain manner is provided.

A description of the branch path in a case in which the four chips 11 are connected in a daisy chain manner will be continued by referring back to FIG. 8. The first branch path is a top branch path and is a branch path without an amount of delay. The second branch path is a branch path in which an end point of a segment that starts from a branch position of the first branch path and to which a delay τa caused by a signal line 131 is added is defined as a branch position. The third branch path is a branch path in which an end point of a segment that starts from the branch position of the second branch path and to which the delay τa caused by a signal line 132 is added is defined as a branch position. The fourth branch path is a branch path in which an end point of a segment that starts from the branch position of the third branch path and to which the delay τa caused by a signal line 133 is added is defined as a branch position. Furthermore, the segment that starts from the branch path of the fourth branch path to the output terminal 162 is also the segment to which the delay τa caused by a signal line 134 is added. In other words, if the branch position of the first branch path is defined as the top position, the second to the fourth branch positions are the positions that divides the signal path starting from the top position to the output terminal 162 into segments in each of which an amount of delay obtained by equally dividing the amount of delay that is added to the signal and that is caused by the signal path is added. Here, the amount of delay obtained by equally dividing the amount of delay that is added to the signal and that is caused by the signal path starting from the top position to the output terminal 162 is τa. Each of the signal lines 131 to 134 is a part of the signal path that connects the input terminal 161 and the output terminal 162.

Furthermore, each of the branch paths returns to the path linked to the branch path and an amplifier 151, the path for returning the subject branch path is a delay addition path, as illustrated in FIG. 8, in which delay addition circuits 101 to 104 are disposed in a row and connected in series. Each of the delay addition circuits 101 to 104 adds the delay τ to the signal that passes through the associated one of the delay addition circuits 101 to 104. The delay τ mentioned here corresponds to an example of a “second amount of delay”. The first branch path is linked to a connection point between the delay addition path and the output terminals 163 and 164 via a variable gain amplifier 111. Furthermore, the second branch path is connected to the delay addition path so as to be connected to the output terminals 163 and 164 by way of the number of delay addition circuits 101 to 103 corresponding to the sum total of the number of branch positions that are present between the top position and the own branch position and a value of 1 that corresponds to a value indicating the top position.

The first branch path is connected to the variable gain amplifier 111 via a switch 121. Then, the variable gain amplifier 111 is connected to the output terminals 163 and 164 via the amplifier 151.

The second branch path is connected to a variable gain amplifier 112 via a switch 122. Then, the variable gain amplifier 112 is connected to the output terminals 163 and 164 via the delay addition circuit 101. The delay addition circuit 101 adds the delay τ.

The third branch path is connected to a variable gain amplifier 113 via a switch 123. Then, the variable gain amplifier 113 is connected to the output terminals 163 and 164 via the delay addition circuits 101 and 102. Each of the delay addition circuits 101 and 102 adds the delay τ.

The fourth branch path is connected to a variable gain amplifier 114 via a switch 124. Then, the variable gain amplifier 114 is connected to the output terminals 163 and 164 via the delay addition circuits 101 to 103. Each of the delay addition circuits 101 to 103 adds the delay τ. Furthermore, the fourth branch path is connected to a terminator 141 via the delay addition circuit 104.

Each of the switches 121 to 124 switches whether to allow the signal that is output from the output terminals 163 and 164 to pass the associated branch paths.

Here, it is conceivable that the distribution delay circuit 100 is configured such that several sets of circuits that add a delay are connected. For example, a combination of the delay addition circuit 101, the variable gain amplifier 111, the switch 121, and the signal line 131 is one set. Furthermore, a combination of the delay addition circuit 102, the variable gain amplifier 112, the switch 122, and the signal line 132 is one set. Furthermore, a combination of the delay addition circuit 103, the variable gain amplifier 113, the switch 123, and the signal line 133 is one set. Furthermore, a combination of the delay addition circuit 104, the variable gain amplifier 114, the switch 124, and the signal line 134 is one set. Then, the same number of sets as the number of daisy stages corresponding to the number of chips 11 connected in a daisy chain manner is disposed in a cascade connection structure. Furthermore, the signal that is output from the distribution delay circuit 100 to the output processing circuit 200 is returned to an input path to the amplifier 151, so that a relationship between a traveling direction of the signal in the daisy chain and a traveling direction of the signal at the time at which a delay is added by each of the delay addition circuits 101 to 103 is a reverse relationship by 180 degrees.

Here, a case in which the switch 121 is turned on and the switches 122 to 124 are turned off is considered. In this case, the signal, out of the signals that are input from the input terminal 161, that is processed by the chip 11 on which the subject distribution delay circuit 100 is mounted is amplified by the variable gain amplifier 111 and the amplifier 151 without an addition of a delay and then output from the output terminals 163 and 164. At this time, the signal other than the signals that are output from the output terminals 163 and 164 is output from the output terminal 162 by way of the signal lines 131 to 134.

Then, a case in which the switch 122 is turned on and the switches 121, 123, and 124 are turned off is considered. The signal, out of the signals that are input from the input terminal 161, that is processed by the chip 11 on which the subject distribution delay circuit 100 is mounted is amplified by the variable gain amplifier 112 after the delay τa is added by the signal line 131. Furthermore, the signal is returned to the path linked to the amplifier 151 after the delay τ is added by the delay addition circuit 101. Then, the signal is amplified by the amplifier 151 and is output from the output terminals 163 and 164. At this time, the signal other than the signals that are output from the output terminals 163 and 164 is output from the output terminal 162 by way of the signal lines 132 to 134. In other words, regarding the signals that are output from the output terminals 163 and 164, a delay of τ−τa is added to the signal that is output from the output terminal 162.

In the following, a case in which the switch 123 is turned on and the switches 121, 122, and 124 are turned off is considered. The signal, out of the signals that are input from the input terminal 161, that is processed by the chip 11 on which the distribution delay circuit 100 is mounted is amplified by the variable gain amplifier 113 after a delay τa×2 is added by each of the signal lines 131 and 132. Furthermore, the signal is returned to the path linked to the amplifier 151 after a delay τ×2 is added by each of the delay addition circuits 101 and 102. Then, the signal is amplified by the amplifier 151 and is output from the output terminals 163 and 164. At this time, the signal other than the signals that are output from the output terminals 163 and 164 is output from the output terminal 162 by way of the signal lines 133 and 134. In other words, regarding the signals that are output from the output terminals 163 and 164, a delay of 2(τ−τa) is added to the signal that is output from the output terminal 162.

In the following, a case in which the switch 124 is turned on and the switches 121 to 123 are turned off is considered. The signal, out of the signals that are input from the input terminal 161, that is processed by the chip 11 on which the subject distribution delay circuit 100 is mounted is amplified by the variable gain amplifier 113 after a delay τa×3 is added by each of the signal lines 131 to 133. Furthermore, the signal is returned to the path linked to the amplifier 151 after a delay τ×3 is added to the signal by each of the delay addition circuits 101 to 103. Then, the signal is amplified by the amplifier 151 and is output from the output terminals 163 and 164. At this time, the signal other than the signals that are output from the output terminals 163 and 164 is output from the output terminal 162 via the signal line 133 and 134. In other words, regarding the signals that are output from the output terminals 163 and 164, a delay of 3(τ−τa) is added to the signal that is output from the output terminal 162. Here, if one of the switches 122 to 124 is turned on, an amount of delay to be added corresponds to a predetermined amount of delay in accordance with a branch position.

Here, for example, in the configuration illustrated in FIG. 8, it is possible to add the delay of 3(τ-τa) at a maximum. Then, as described above, if the four chips 11 are connected in a daisy chain manner in order to perform multiplexing four beams, a shift of the transmission timing of each of the transmission signals is 1/10 of the data bandwidth. Thus, in this case, it is preferable to decrease a shift of the transmission timing of the transmission signal as much as possible by adding a delay to decrease the shift smaller than or equal to 1/10 of the wavelength with respect to the data bandwidth. Thus, if the four chips 11 are connected in a daisy chain manner, it is preferable to design the delay addition circuits 101 to 104 in the distribution delay circuit 100 such that 3(τ-τa) is smaller than or equal to 1/10 of the wavelength with respect to the data bandwidth.

Specifically, in the case where a bandwidth is 400 MHz, a single wavelength is 2.5 ns, and 1/10 of the wavelength is 250 ps. Accordingly, in this case, the delay addition circuits 101 to 104 are preferably designed such that 3(τ−τa) is equal to or less than 250 ps. Furthermore, in the case where a bandwidth is 800 MHz, a single wavelength is 1.25 ns, and 1/10 of the wavelength is 125 ps. Accordingly, in this case, the delay addition circuits 101 to 104 is preferably designed such that 3(τ−τa) is equal to or less than 125 ps.

Furthermore, it is preferable to determine a gain in accordance with the delay addition circuits 101 to 104 and the signal lines 131 to 134 such that each of the variable gain amplifiers 111 to 114 applies the same gain to the signals passing through any of the paths when the signals are input to the amplifier 151.

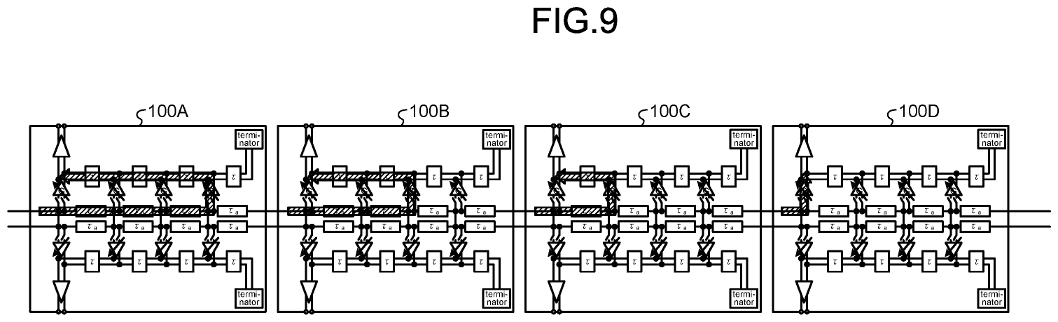

FIG. 9 is a diagram illustrating the distribution delay circuits connected in a daisy chain manner. For example, as illustrated in FIG. 9, a case in which, as the distribution delay circuits 100, distribution delay circuits 100A to 100D are connected in a daisy chain manner will be described.

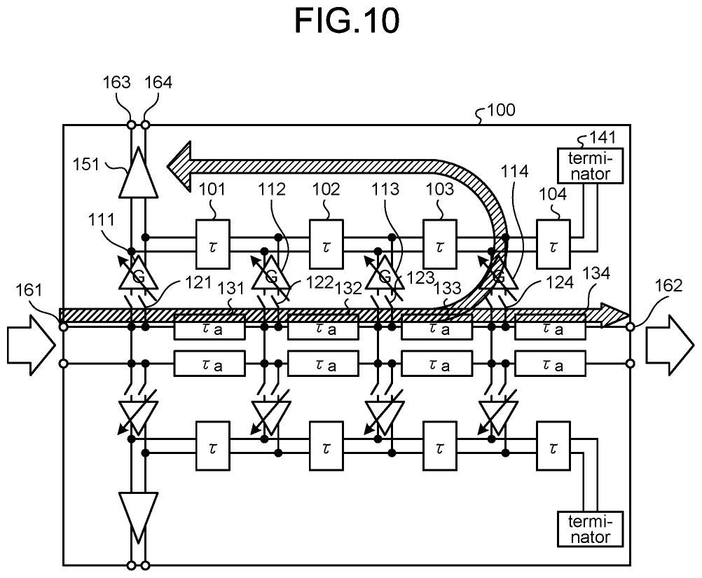

Here, the distribution delay circuit 100A is the top of the daisy chain, and after this, the distribution delay circuit 100B, the distribution delay circuit 100C, and the distribution delay circuit 100D are connected in this order. Then, in the distribution delay circuit 100A, the switch 124 is turned on, and the switches 121 to 123 are turned off. FIG. 10 is a diagram illustrating the flow of the signal in the distribution delay circuit that is located at the top. For example, in the distribution delay circuit 100A illustrated in FIG. 9, as illustrated in FIG. 10, the signal that is output from the distribution delay circuit 100A to the output processing circuit 200 flows along a path R1. In contrast, the signal that is output from the distribution delay circuit 100A to the distribution delay circuit 100B flows along a path R2. In this case, the delay of 3(τ−τa) is added to the signal flowing through the path R1 as compared to the signal flowing through the path R2.

Similarly, in the distribution delay circuit 100B illustrated in FIG. 9, the delay of 2(τ−τa) is added to the signal that is output to the output processing circuit 200. Furthermore, in the distribution delay circuit 100C, the delay of τ−τa is added to the signal that is output to the output processing circuit 200. Then, in the distribution delay circuit 100D, the signal is output to the output processing circuit 200 without an addition of a delay.

Accordingly, an error at the transmission timing of the signal that is output from each of the distribution delay circuits 100A to 100D is reduced, and thus, it is possible to perform transmission at closer timings.

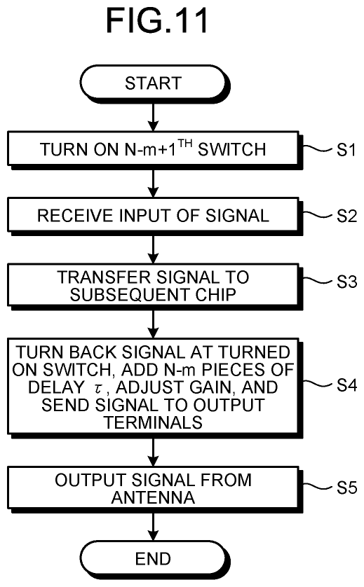

FIG. 11 is a flowchart illustrating the flow of the flowchart performed in the distribution delay circuit. In the following, the flow of the signal output process performed in the distribution delay circuit 100 will be described with reference to FIG. 11. Here, a case in which N pieces of the chip 11 are connected in a daisy chain manner will be described. Furthermore, the following description is an example of the chip 11 at the top to the m^{th} (1≤m≤N) chip 11 that are connected in a daisy chain manner. In a description below, each of the switches 121 to 124 disposed in the distribution delay circuit 100 are simply referred to as a switch 120 without distinguishing the switches 121 to 124.

The distribution delay circuit 100 sequentially turns on the top to the N−m+1^{th} switches 120 in the transmission direction of the signal, and turns off the other switch 120 (Step S1).

The distribution delay circuit 100 receives an input of the signal to the input terminal 161 (Step S2).

The distribution delay circuit 100 branches the signal at the branch path linked to the switch 120 that has been turned on, and transfers the signal other than the signals that are output to the output processing circuit 200 to the subsequent chip 11 that is connected in a cascade connection structure (Step S3).

Furthermore, the distribution delay circuit 100 turns back the signal to be output to the output processing circuit 200 at the switch 120 that is turned on, adds the N−m pieces of delay τ, adjusts the gain, and sends the signal to the output terminals 163 and 164 (Step S4). In this case, a delay of (N−m)×(τ−τa) is added to the signal that is to be output to the output processing circuit 200 as compared to the signal that has been transferred to the subsequent chip 11.

After that, the distribution delay circuit 100 outputs the signal from each of the output terminals 163 and 164 and sends the signal to the output processing circuit 200. The output processing circuit 200 performs orthogonal transformation on the signal that is input from the distribution delay circuit 100 and performs up-conversion on the wavelength, and then, the output processing circuit 200 outputs the signal from the antenna 4 (Step S5).

As described above, the chips that are used for beam multiplexing according to the present embodiment are connected in a daisy chain manner, and also, matches the output timings of the signals by adding a different delay in accordance with the disposition position in the daisy chain layout. Furthermore, the chips are able to substantially match the output gains by applying a gain to each of the signals to each of which a delay is added such that the gains of the output signals are matched. As a result, it is possible to align the phase and the amplitude among the signals to be multiplexed, and it is thus possible to improve signal quality.

Furthermore, the distribution delay circuit according to the present embodiment has a configuration in which the delay addition circuit, the variable gain amplifier, the signal line, and the switch are used as a set, and a plurality of sets are connected in a cascade connection structure. As a result, by changing the switch that is to be turned on even if the distribution delay circuits are disposed at any position in a daisy chain manner, the distribution delay circuit is able to add the delay and the gain in accordance with the disposition position. Accordingly, it is possible to easily manufacture and implement the chips, and it is thus possible to reduce a manufacturing cost.

### [b] Second Embodiment

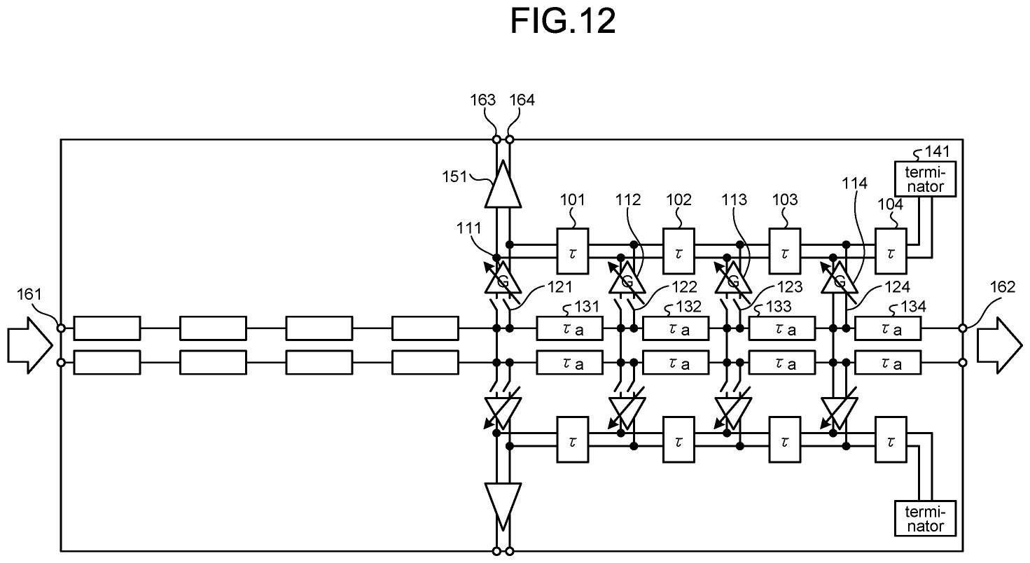

FIG. 12 is a circuit configuration diagram of a distribution delay circuit according to a second embodiment. The distribution delay circuit 100 according to the present embodiment is different from the first embodiment in that, in the distribution delay circuit 100, each of the sets to which a delay is added is disposed at a latter half part of the Daisy line that links the input terminal 161 to the output terminal 162 that corresponds to transmission paths for the signal transmitted in a daisy chain manner.

In the distribution delay circuit 100 according to the present embodiment, the first branch path that is linked to the switch 121 and that receives an input to the amplifier 151 via the variable gain amplifier 111 is disposed at an intermediate position in the Daisy line that links the input terminal 161 to the output terminal 162. Then, the other branch paths are disposed at the positions obtained by equally dividing the distance between the subject branch path and the output terminal 162 by the number of Daisy stages.

For example, FIG. 12 is a configuration used in a case of multiplexing four beams, and, in this case, branch paths that returns at the switches 122 to 124 are disposed at three positions that divide the distance between an intermediate position of the Daisy line that links the input terminal 161 to the output terminal 162 and the output terminal 162 into four equal parts.

In this case, the delay τa that is added by the signal lines 131 to 134 corresponds to a value obtained by dividing a half of an amount of delay of the entirety of the Daisy line that links the input terminal 161 to the output terminal 162 into four equal parts.

The chips 11 according to the present embodiment are also connected in a daisy chain manner, and the switch to be turned on is determined in accordance with each of the positions located in the daisy chain. In other words, if N chips 11 are connected in a daisy chain manner, in the distribution delay circuit 100 on the m^{th} chip 11 from the top, the N−m+1^{th} switch from the top located in the traveling direction of the signal is turned on, and the other switches are turned off.

Each of the signals are uniformly sent up to the intermediate position of the Daisy line that links the input terminal 161 to the output terminal 162. After that, the signals that are output to the output processing circuit 200 are returned and sent to the amplifier 151 after a delay is added by the delay addition circuits 101 to 104 in accordance with the position of the switches 121 to 124. The signal other than the signals that are output to the output processing circuit 200 is sent to the output terminal 162 and is output to the subsequent chip 11.

In this case, also, the delays of τ−τa, 2(τ−τa), and 3(τ−τa) are added to the signals passing through the switches 122 to 124, respectively, as compared to the signal that is sent to the subsequent chip 11. In addition, a delay is not added to the signal that passes through the switch 121. Accordingly, even in the distribution delay circuit 100 according to the present embodiment, it is preferable that the delay addition circuits 101 to 104 is designed such that 3(τ−τa) is smaller than or equal to 1/10 of the wavelength with respect to the data bandwidth.

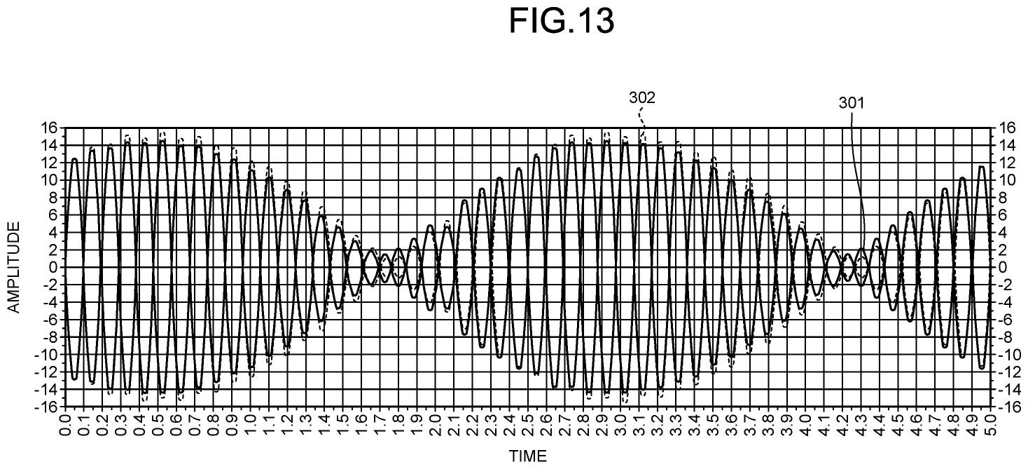

FIG. 13 is a diagram illustrating the waveform output in a case of using the distribution delay circuit according to the second embodiment. In FIG. 6, the horizontal axis indicates time, whereas the vertical axis indicates an amplitude. FIG. 13 illustrates a simulation result in the case where, as an example of a modulation wave, a two-tone signal is input to the chips 11 that are connected in a daisy chain manner.

Here, a description will be given in a case in which the four chips C1 to C4 are connected in a daisy chain manner. A waveform 301 illustrated in FIG. 13 indicates the waveform of the signal that is output from the chip C1. Furthermore, a waveform 302 indicates the waveform of the signal that is output from the chip C4. Timings of both of the waveforms 301 and 302 are matched, and thus, it can be said that a propagation delay of the transfer among the chips C1 to C4 that are connected in a daisy chain manner is appropriately compensated.

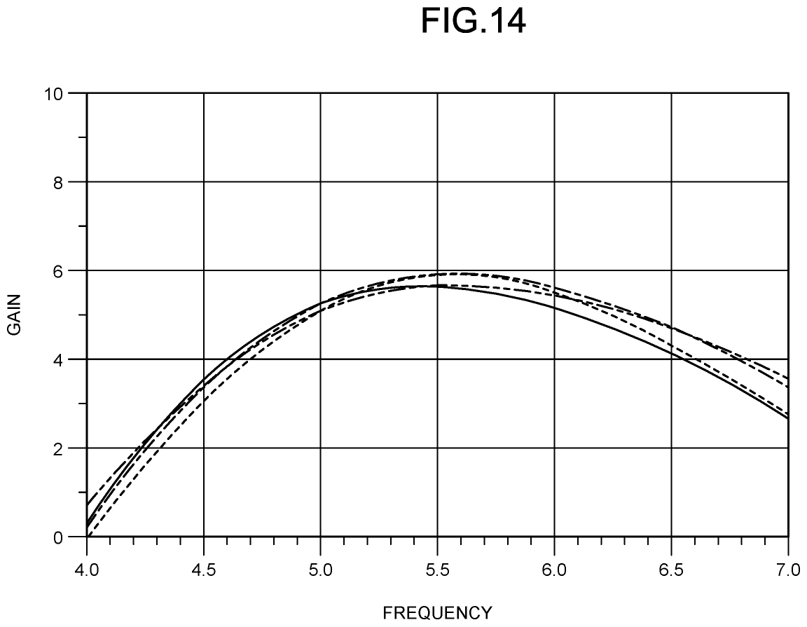

Furthermore, FIG. 14 is a diagram illustrating the gain characteristic of an output of each of the chips in a case of using the distribution delay circuit according to the second embodiment. In FIG. 14, the horizontal axis indicates a frequency, whereas the vertical axis indicates a gain. Each of the curves illustrated in FIG. 14 indicates the gain of each of frequencies output from the four chips C1 to C4 that are connected in the daisy chain manner. As illustrated in FIG. 14, the gains that are output from the chips C1 to C4 are substantially the same. As a result, it is found that the delay and the amplitude difference generated among the chips C1 to C4 that are connected in a daisy chain manner are appropriately compensated.

As described above, in the distribution delay circuit according to the present embodiment, each of the sets to which a delay is added is disposed at the latter half part of the Daisy line in a cascade connection structure. Then, by switching the switches in accordance with the position of each of the chips in the case of being connected in a daisy chain manner, it is possible to adjust the phase and the amplitude that are output from each of the chips.

As described above, by disposing each of the sets to which a delay is added is disposed at the latter half part of the Daisy line in a cascade connection structure, there is no need to consider a shift by an amount of delay of a half of the Daisy line when considering a difference of the amount of delay between the signal that is output toward the antenna and the signal that is transferred to the subsequent chip. In other words, it is possible to suppress an amount of delay to be added to the signal that is output toward the antenna, and it is thus possible to reduce a loss in the intensity of the signal; therefore, it is possible to improve signal quality.

Here, in the present embodiment, the intermediate point is defined as the top position of the branch path; however, the top position may be any position on the Daisy line. In this case, the branch paths are arranged by setting, as each of the branch positions, the position obtained by equally dividing the entire amount of delay occurring from the top position to the output terminal 162 into equal number of chips 11 that are connected in a daisy chain manner.

According to an aspect of an embodiment of the present invention, it is possible to improve signal quality.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A signal processing circuit comprising:
a signal path for outputting a first signal included in an input signal from a first output terminal to another signal processor;
branch paths
one of which extends from a top position located at a position on the signal path and
the others of which extend from associated branch positions that divide the signal path starting from the top position to the first output terminal into segments in each of which a first amount of delay that is obtained by equally dividing an amount of delay that is caused by the signal path and that is added to the first signal is added;
a switch that is connected to each of the branch paths and that switches whether to allow a second signal other than the first signal included in the input signal to pass through the connected branch paths;
a variable gain amplifier that is connected to each of the switches and that amplifies the second signal; and
a delay adding unit that
adds a predetermined amount of delay to the second signals that are output from the respective variable gain amplifiers in accordance with the branch positions to which the respective branch paths through which the respective second signals pass are connected, and
outputs the second signals from a second output terminal.

2. The signal processing circuit according to claim 1, wherein
predetermined number of other signal processing circuits are connected with the signal processing circuit in a daisy chain manner, and
the same number of the branch paths as a number of the signal processing circuits is provided.

3. The signal processing circuit according to claim 1, wherein
the delay adding unit includes a delay addition path that is connected to the second output terminal and in which a plurality of delay addition circuits that adds a second amount of delay are disposed in series connection,
the branch path extending from the top position is connected to a connection point between the delay addition path and the second output terminal via the variable gain amplifier, and
the branch paths extending from the respective branch positions are connected, via the respective variable gain amplifiers, to positions on the delay addition path connected to the second output terminal by way of the number of delay addition circuits corresponding to a total count of branch positions, which are present between the top position and the own branch position, and the top position.

4. The signal processing circuit according to claim 3, wherein the delay addition circuit, the variable gain amplifier, and the switch are defined as a set and a plurality of sets are connected in series.

5. The signal processing circuit according to claim 3, wherein
other three signal processing circuits are connected with the signal processing circuit in a daisy chain manner, and
in the delay addition circuit, the second amount of delay is determined such that a calculation result obtained by subtracting a value equal to three times the first amount of delay from a value equal to three times the second amount of delay is smaller than or equal to 1/10 of data bandwidth of the input signal.

6. The signal processing circuit according to claim 1, wherein the top position is an intermediate point of the signal path.

7. The signal processing circuit according to claim 1, further comprising:
an amplifier that amplifies a signal that is output from the second output terminal; and
an output processing circuit that performs a predetermined signal process on the signal that is output from the second output terminal and that is amplified by the amplifier and that outputs the signal as a radio signal having a millimeter wave from a field array antenna.
